(19) United States
(12) Patent Application Publication
(10) Pub. No.: US 2011/0253126 A1
(43) Pub. Date: Oct. 20, 2011

(54) Net Zero Energy Building System

(76) Inventors: Huiming Yin, New York, NY (US); C. Julian Chen, White Plains, NY (US)

(21) Appl. No.: 13/088,111

(22) Filed: Apr. 15, 2011

Related U.S. Application Data
(60) Provisional application No. 61/324,626, filed on Apr. 15, 2010.

(51) Int. Cl. E04D 13/18; F01K 25/08; F24J 2/30; F24J 2/04; H01L 35/30

(52) U.S. Cl. 126/622; 126/634; 126/640; 136/205; 126/644; 126/679; 60/651

(57) ABSTRACT

Net zero energy building systems are disclosed. In some embodiments, the systems include the following: roofing panels positioned on a roof of a building, the roofing panels being made of an array of horizontal elliptic glass vacuum tube solar collectors attached upon a reinforced light weight concrete panel; electricity generators; an insulated fluid storage tank; and a fluid circulation sub-system joined with the panels, generators, and tank.

### CROSS REFERENCE TO RELATED APPLICATION(S)

This application claims the benefit of U.S. Provisional Application No. 61/324,626, filed Apr. 15, 2010, which is incorporated by reference as if disclosed herein in its entirety.

### BACKGROUND

A net zero energy building (ZEB) is building, either residential or commercial, that is built so as to require and/or consume less energy than conventional buildings. In addition, with ZEB, renewable technologies are utilized so that the net energy consumption by the building is zero.

Buildings consume a significant amount of the energy generated in the United States. Commercial and residential buildings use almost 40% of the primary energy and approximately 70% of the overall electricity consumed in the United States. Because of the rapid rate of development, energy utilized by buildings continues to increase. For example, electricity consumption by commercial buildings increased by 100% between 1980 and 2000, and is expected to continue to increase significantly over the next twenty-five years. Currently, there are few cost-effective ZEBs, either residential or commercial.

### SUMMARY

Some embodiments of the disclosed subject matter include a “net zero energy building system,” which is a building that uses no external energy overall for the operation of the building. Such buildings are an important step in reducing greenhouse gas emission, dependence on fossil fuels, and for sustainable development. Building designs according to the disclosed subject matter includes integrated solar heating, power, and energy storage systems including at least four components: roofing panels; electricity generators; an insulated fluid storage tank; and a fluid circulation system connecting with all above three parts. The disclosed subject matter details a design to integrate solar, thermodynamic, and thermoelectric modules into a building to provide heating and electricity. Designs according to the disclosed subject matter satisfy requirements in architecture, esthetic appearance, indoor air quality, mechanical strength, durability, thermal efficiency, sound absorption, and moisture migration.

### BRIEF DESCRIPTION OF THE DRAWINGS

The drawings show embodiments of the disclosed subject matter for the purpose of illustrating the invention. However, it should be understood that the present application is not limited to the precise arrangements and instrumentalities shown in the drawings, wherein:

FIG. 1 is a schematic diagram of systems according to some embodiments of the disclosed subject matter; and

FIG. 2 a schematic diagram of systems according to some embodiments of the disclosed subject matter.

### DETAILED DESCRIPTION

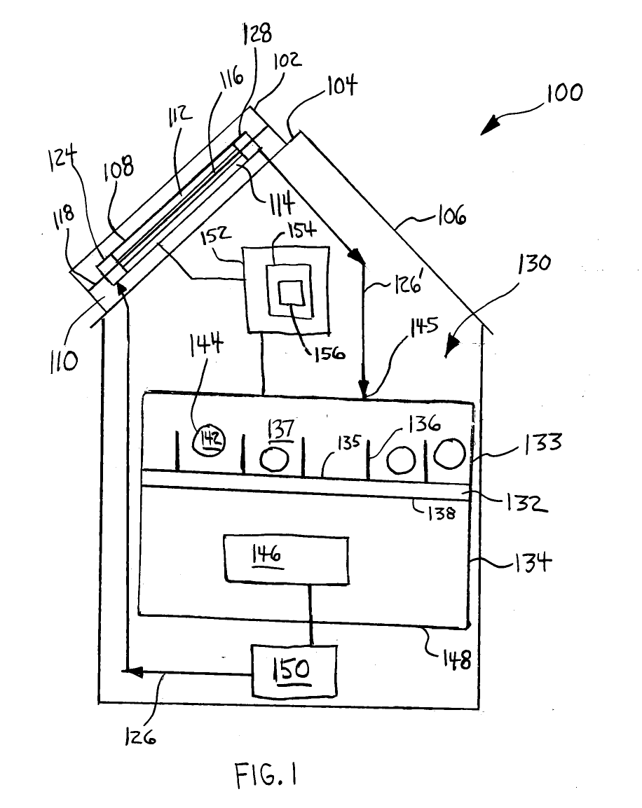

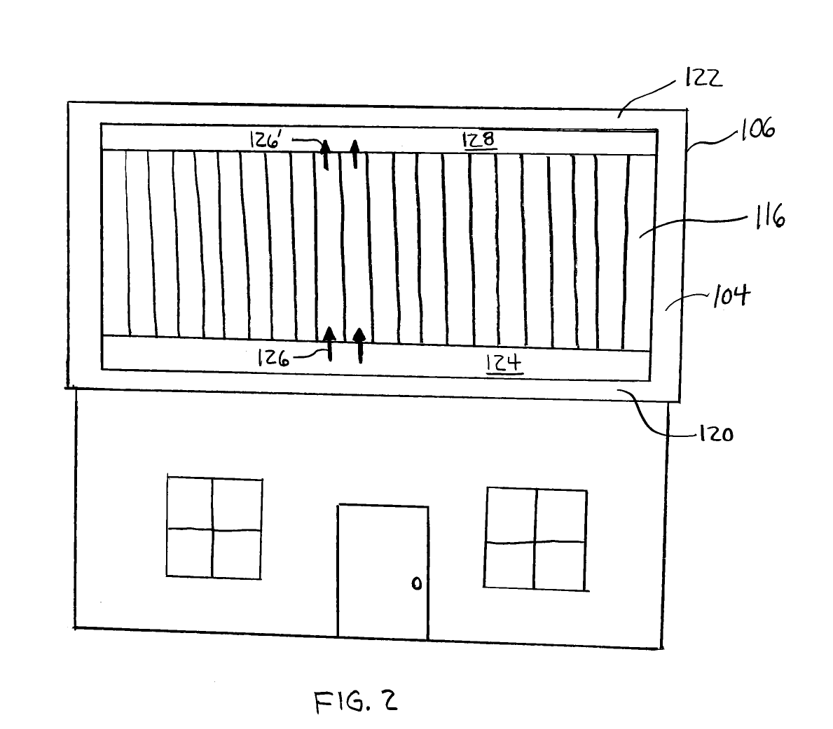

Referring now to FIGS. 1 and 2, aspects of the disclosed subject matter include systems a net zero energy building system 100. System 100 includes roofing panels 102 positioned on a roof 104 of a building 106.

Roofing panels 102 are made of an array of horizontal elliptic glass vacuum tube solar collectors 108 attached upon a reinforced light weight concrete panel 110. A top half 112 of each of tube solar collectors 108 is typically substantially transparent and a bottom half 114 is typically glazed with a substantially reflective paint and embedded into concrete panel 110. In some embodiments, the major diameter of ellipse of collectors 108 is about 4 to 6 inches, the minor diameter is about 1.5 to 2.5 inches, and the thickness of the tube is about 1/16 inch. A spacing of about 0.5 inch between each of collectors 108 is reserved to form a smoothly corrugated roof surface. In some embodiments, below vacuum tube collectors 108, light weight concrete panel 110 includes glass fiber reinforcement (not shown) having a thickness of about ¼ inch provides mechanical support for the panel. In some embodiments, roofing panel 102 is about 2 meters by 0.5 meter. Of course, the size of roofing panel 102 can vary depending upon the particular application.

Within each of vacuum tube solar collectors 108, a heat pipe collector 116 is fixed along a center line 118. Pipe collector 116 is typically made of thin wall copper coated with copper black (CuO) to obtain a high solar radiation absorption, e.g., about 93%, and a low heat emissivity, e.g., about <10%. Pipe collector 116 typically has a horizontally elliptic section to absorb all solar radiation reflected by bottom half 114 of collector 118. As shown in FIG. 2, heat pipe collectors 116 are connected in series from a bottom 120 to a top 122 of roof 104. At bottom 120 of roof 104, heat pipe collectors 116 are connected to an intake manifold 124 to feed a cold working fluid 126 and at a top 122 of the roof; the heat pipe collectors are connected to an outlet manifold 128 to collect a hot working fluid 126′. In some embodiments, working fluid 126, 126′ is made of synthetic oil, which keeps in the fluid phase up to 350 degrees Celsius or higher. When the working fluid moves slowly from the bottom of the roof to the top, with the concentrated solar radiation and vacuum insulation, the temperature will increase to a high temperature, about 210 degrees Celsius.

Referring again to FIG. 1, system 100 includes electricity generators 130. In some embodiments, a thermoelectric module 132 is positioned at a top 133 of an insulated fluid storage tank 134. A hot side 135 of module 132 is made of copperplate with fins 136 extended into a porous structure 137. A cold side 138 is made of a copper plate with copper pipes. Water and ORC liquid flows through module 132 so that hot water can be obtained for indoor usage and ORC liquid is used to collect the heat and generate electricity. Insulated fluid storage tank 134 is typically made of a foam polyurethane having a thermal conductance of about 0.025 W/mK.

In some embodiments, a phase change material (PCM) 142 such as MgCl₂, which has a melting point 117 degrees Celsius, is encapsulated in metal cans 144 in storage tank 134 to store thermal energy. When heated working fluid 126′ flows into tank 134 from a top inlet 145, it will pass porous structure 137 and heat up cans 144. PCM 142 will be transformed from a solid to a liquid, so that a large portion of energy will be stored in cans 144 as latent heat. In some embodiments, an organic Rankine cycle (ORC) engine 146 is positioned at a bottom 148 of storage tank 134 so the heat will be collected by low boiling liquid for electricity generation. After the ORC process, working fluid 126′ is cooled down. The cold fluid 126 is transferred through a pump 150 to roof intake manifold 124 again.

A fluid circulation sub-system 152 is joined with panels 104, generators 130, and tank 134. Fluid circulation sub-system 152 includes a computer 154 and a computer program 156 for controlling the flow rate of working fluid 126, 126′ to get a desired temperature. The fluid temperature at intake and outlet manifolds 124, 128 is sensed and sent to computer 154. Computer program 156 controls the flow rate to get a desired temperature of working fluid 126, 126′. Heated working fluid 126′ will flow to insulated tank 134.

In use, system 100 typically works as follows: First, in the morning, the cold synthetic oil will be pumped to the roof, and hot synthetic oil flows into the tank to heat up the capsules. Although the temperature of the oil may much cool down, it can be used by ORC to generate electricity. At daytime, the thermoelectric modules will not have to work until a stable high temperature above 117 degrees Celsius is achieved. Next, once the copper plate is heated up to a high temperature, say 160 degrees Celsius, the thermoelectric generator will be turned on, and ORC liquid will be used at cold side to generate electricity. Then, at evening or night, no heated synthetic oil can be obtained, the liquid in the cold side of thermoelectric modules will be turned on, so electricity can be obtained by both thermoelectric modules and the ORC engine. At anytime, if hot water is needed, water will flow through the pipes in thermoelectric modules, so hot water and electricity can be obtained. This system is the first step towards net zero energy/water house.

The disclosed subject matter includes a “net zero energy building system,” which is a building that uses no external energy overall for the operation of the building. Designs according to the disclosed subject matter offer benefits over known designs and buildings according to the disclosed subject matter are an important step in reducing greenhouse gas emission, dependence on fossil fuels, and for sustainable development. The disclosed subject matter details a design to integrate solar, thermodynamic, and thermoelectric modules into a building to provide heating and electricity. Designs according to the disclosed subject matter satisfy requirements in architecture, esthetic appearance, indoor air quality, mechanical strength, durability, thermal efficiency, sound absorption, and moisture migration.

Although the disclosed subject matter has been described and illustrated with respect to embodiments thereof, it should be understood by those skilled in the art that features of the disclosed embodiments can be combined, rearranged, etc., to produce additional embodiments within the scope of the invention, and that various other changes, omissions, and additions may be made therein and thereto, without parting from the spirit and scope of the present invention.

What is claimed is:

1. A net zero energy building system, said system comprising:
roofing panels positioned on a roof of a building, said roofing panels being made of an array of horizontal elliptic glass vacuum tube solar collectors attached upon a reinforced light weight concrete panel;
electricity generators;
an insulated fluid storage tank; and
a fluid circulation sub-system joined with said panels, generators, and tank.

2. The system of claim 1, wherein a top half of each of the tube solar collectors is transparent and a bottom half is glazed with reflective paint and embedded into the concrete panel.

3. The system of claim 1, further comprising within each of the vacuum tube solar collectors, a heat pipe collector is fixed along a center line, said pipe being made of thin wall copper coated with copper black (CuO) to obtain a high solar radiation absorption.

4. The system of claim 3, wherein the heat pipe collectors are connected in series from the bottom to the top and at a bottom of the roof, the heat pipe collectors are connected to an intake manifold to feed cold working fluid and at a top of the roof, the heat pipe collectors are connected to an outlet manifold to collect hot working fluid.

5. The system of claim 4, wherein the working fluid is made of synthetic oil.

6. The system of claim 1, the fluid circulation sub-system further comprising a computer and a computer program for controlling the flow rate to get a desired temperature of the working fluid.

7. The system of claim 1, wherein the insulated fluid storage tank is made of foam polyurethane having a thermal conductance of about 0.025 W/mK.

8. The system of claim 1, wherein a phase change material (PCM) such as MgCl2 is encapsulated in metal cans in said storage tank to store thermal energy.

9. The system of claim 1, further comprising an organic Rankine cycle (ORC) engine positioned at a bottom of the storage tank so the heat will be collected by low boiling liquid for electricity generation.

10. The system of claim 1, further comprising a thermoelectric module positioned at a top of the storage tank, wherein water and ORC liquid flows through the module so that hot water can be obtained for indoor usage and ORC liquid is used to collect the heat and generate electricity.

11. A net zero energy building system, said system comprising:
roofing panels positioned on a roof of a building, said roofing panels including an array of horizontal elliptic glass vacuum tube solar collectors attached upon a reinforced light weight concrete panel, said tube solar collectors including a top half that is transparent and a bottom half that is glazed with reflective paint and embedded into the concrete panel;
electricity generators;
an insulated fluid storage tank; and
a fluid circulation sub-system joined with said panels, generators, and tank.

12. The system of claim 11, further comprising a heat pipe collector is fixed along a center line within each of the vacuum tube solar collectors, said pipe being made of thin wall copper coated with CuO (copper black) to obtain a high solar radiation absorption.

13. The system of claim 12, wherein the heat pipe collectors are connected in series from the bottom to the top and at a bottom of the roof, the heat pipe collectors are connected to an intake manifold to feed cold working fluid and at a top of the roof, the heat pipe collectors are connected to an outlet manifold to collect hot working fluid.

14. The system of claim 11, further comprising an organic Rankine cycle (ORC) engine positioned at a bottom of the storage tank so the heat will be collected by low boiling liquid for electricity generation.

15. The system of claim 11, further comprising a thermoelectric module positioned at a top of the storage tank, wherein water and ORC liquid flows through the module so that hot water can be obtained for indoor usage and ORC liquid is used to collect the heat and generate electricity.

16. A net zero energy building system, said system comprising:
roofing panels positioned on a roof of a building, said roofing panels being made of an array of horizontal elliptic glass vacuum tube solar collectors attached upon a reinforced light weight concrete panel;
electricity generators;
an insulated fluid storage tank; and
a fluid circulation sub-system joined with said panels, generators, and tank, wherein the fluid circulation sub-system includes a computer and a computer program for controlling the flow rate to get a desired temperature of a working fluid.

17. The system of claim 16, wherein a top half of each of the tube solar collectors is transparent and a bottom half is glazed with reflective paint and embedded into the concrete panel.

18. The system of claim 16, further comprising:
a heat pipe collector is fixed along a center line within each of the vacuum tube solar collectors, said pipe being made of thin wall copper coated with copper black (CuO) to obtain a high solar radiation absorption.

19. The system of claim 18, wherein the heat pipe collectors are connected in series from the bottom to the top and at a bottom of the roof, the heat pipe collectors are connected to an intake manifold to feed cold working fluid and at a top of the roof, the heat pipe collectors are connected to an outlet manifold to collect hot working fluid.

20. The system of claim 16, further comprising:
an organic Rankine cycle (ORC) engine positioned at a bottom of the storage tank so the heat will be collected by low boiling liquid for electricity generation; and
a thermoelectric module positioned at a top of the storage tank, wherein water and ORC liquid flows through the module so that hot water can be obtained for indoor usage and ORC liquid is used to collect the heat and generate electricity.
